(19) United States
(12) Patent Application Publication
(10) Pub. No.: US 2004/0002210 A1
(43) Pub. Date: Jan. 1, 2004

(54) Interconnect structure and method for forming

(76) Inventors: Cindy K. Goldberg, Austin, TX (US); Yeong-Jyn T. Lii, Austin, TX (US)

Correspondence Address: MOTOROLA INC, AUSTIN INTELLECTUAL PROPERTY, LAW SECTION, 7700 WEST PARMER LANE MD: TX32/PL02, AUSTIN, TX, 78729

(21) Appl. No.: 10/184,858

(22) Filed: Jun. 28, 2002

(51) Int. Cl. H01L 21/3205

(52) U.S. Cl. 438/637

(57) ABSTRACT

An interconnect structure with a via (66) embedded in a first low dielectric constant material (44) and a trench (66) embedded in a second low dielectric constant material (48), which is a different material than the first low dielectric constant material (44), is formed. In one embodiment, the second low dielectric constant material (48) is used as a mask for etching the first low dielectric constant material (44). Also, in one embodiment, the first low dielectric constant material (44) may be used as an etch stop layer for etching the second low dielectric constant material. The second low dielectric constant material (48) may include silicon and oxygen and the first low dielectric constant material (44) may be organic.

### FIELD OF THE INVENTION

The present invention relates generally to semiconductor devices, and more specifically, to interconnect formation.

### RELATED ART

Within semiconductor devices, interconnects are generally used to route signals among transistors and to route signals between transistors and package inputs and outputs. Therefore, a semiconductor device generally includes many metal layers to provide the signal routing. The metal layers include conductor filled trenches which are used to route signals (e.g. via metal lines) within a same metal layer, while conductor filled vias are used to route signals between different metal layers. A dual inlaid interconnect structure refers to a conductor filled via and an overlying conductor filled trench.

One current method of forming a dual inlaid interconnect structure includes forming a single dielectric material for both the interlayer dielectric (the portion of the dielectric layer adjacent to the conductor filled via, also referred to as via-level dielectric) and the intralayer dielectric (the portion of the dielectric layer adjacent to the conductor filled trench, also referred to as metal-level dielectric). In defining the depth of the trench opening, a timed etch is used. However, the timed etch results in an undesired variation in trench depth across both the die and the wafer. The variation in trench depth translates to variations in resistance and subsequent variation in semiconductor performance. Furthermore, the timed etch produces a rough etch front, depending on the dielectric material used. Another method of defining the depth of the trench opening employs an etch stop layer between the interlayer dielectric and intralayer dielectric. However, the etch stop layer typically has a dielectric constant higher than the single dielectric material used for the interlayer and intralayer dielectric, resulting in an increased capacitance and subsequent performance loss. Therefore, a need exists for forming an interconnect structure which provides for improved control of trench depth without an increase in capacitance.

### BRIEF DESCRIPTION OF THE DRAWINGS

The present invention is illustrated by way of example and not limited by the accompanying figures, in which like references indicate similar elements, and in which:

FIG. 1 illustrates a portion of a semiconductor substrate having a transistor in accordance with one embodiment of the present invention;

FIGS. 2-5 illustrate a process of forming a via opening in accordance with one embodiment of the present invention;

FIGS. 6-7 illustrate a process of forming a trench opening overlying the via opening in accordance with one embodiment of the present invention; and

FIG. 8 illustrates a resulting interconnect structure formed according to one embodiment of the present invention.

Skilled artisans appreciate that elements in the figures are illustrated for simplicity and clarity and have not necessarily been drawn to scale. For example, the dimensions of some of the elements in the figures may be exaggerated relative to other elements to help improve the understanding of the embodiments of the present invention.

### DETAILED DESCRIPTION OF THE DRAWINGS

Embodiments of the present invention allow for a reduced capacitance interconnect structure which provides for improved control of trench depth. One embodiment uses a first low K material for the interlayer dielectric (at the via level) and a second low K material for the intralayer dielectric (at the trench level). One embodiment etches through the intralayer dielectric using an etch chemistry that is selective to the interlayer dielectric to achieve a more controllable trench depth without the need of a separate etch stop layer between the interlayer and intralayer dielectric. Also, in one embodiment, an etch chemistry that is selective to the intralayer dielectric is used which allows for the intralayer dielectric to be used as a hardmask for etching through the interlayer dielectric.

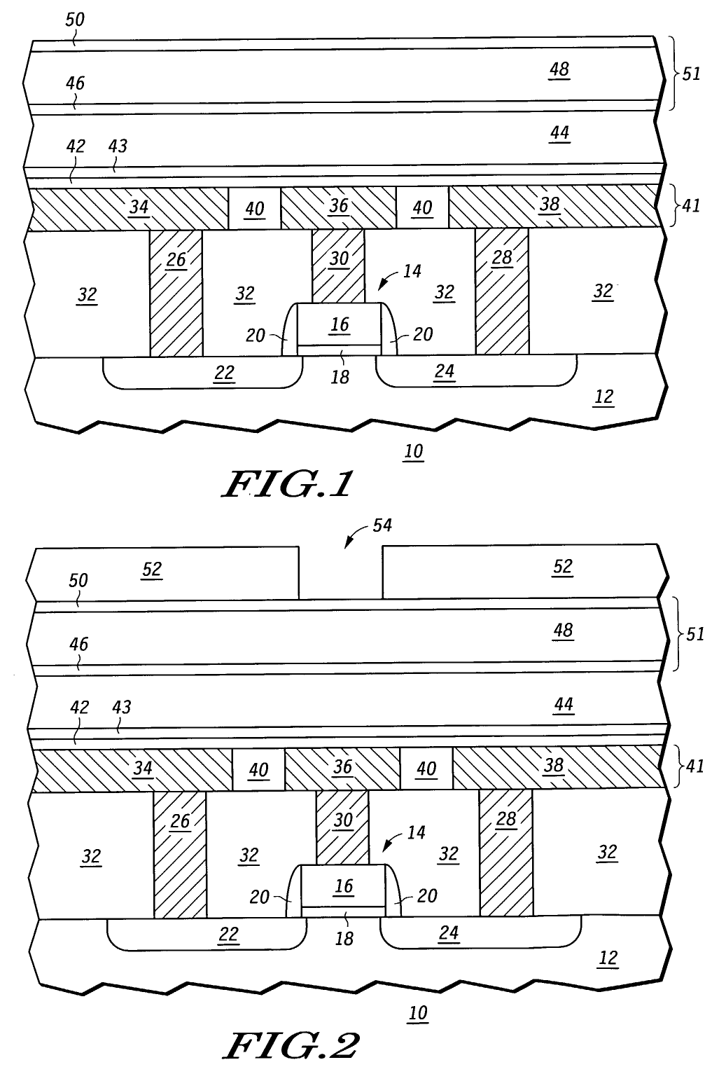

FIG. 1 illustrates one embodiment of a portion of a semiconductor device 10 during the process of forming an interconnect structure. (Note that the portion illustrated in FIG. 1 can be part of a larger semiconductor integrated circuit, die, or wafer.) Semiconductor device 10 includes a semiconductor substrate 12 having source/drain region 22 and source/drain region 24. Semiconductor substrate 12 can be any type of material, such as, for example, a bulk silicon substrate, a silicon-on-insulator substrate, a gallium arsenide substrate, etc. Semiconductor device 10 also includes a gate dielectric 18 overlying semiconductor substrate 12, a gate 16 overlying the gate dielectric 18, and spacers 20 lying along the sidewalls of gate 16 and gate dielectric 18. Therefore, gate 16, gate dielectric 18, sidewall spacers 20, and source/drain regions 22 and 24 form a transistor 14. Semiconductor device 10 includes a contact level dielectric 32 overlying substrate 12 and transistor 14. Source/drain contacts 26 and 28 and gate contact 30 are conductors embedded within contact level dielectric 32 and provide electrical connections from terminals of transistor 14 to a first metal layer 41. First metal layer 41 includes conductor filled trenches 34, 36, and 38 which route signals from transistor 14 within first metal layer 41. (Note that first metal layer 41 may also be referred to as patterned metal or conductive layer 41.) The conductor filled trenches 34, 36, and 38 are embedded in intralayer dielectric 40. Intralayer dielectric 40 may include silicon dioxide, doped silicon dioxide, or any low K dielectric. Alternatively, intralayer dielectric 40 may include a stack of different dielectric materials.

In the illustrated embodiment, transistor 14 is formed within semiconductor device 10; however, alternate embodiments may have a variety of different devices or combination of devices needing electrical connections to the first metal layer. Therefore, note that transistor 14 is only one example. Also, in one embodiment of the present invention, source/drain region contacts 26 and 28 and gate contact 30 are conductors which may be formed of any conductive material or combination of conductive materials, such as, for example, tungsten, copper, aluminum, etc. For example, in one embodiment, the contacts 26, 28, and 30 may include a liner layer such as, for example, titanium, titanium nitride, tantalum, tantalum nitride, etc. Contact level dielectric 32 may include silicon dioxide, doped silicon dioxide, or any dielectric having a low dielectric constant, or any combination of dielectric materials. (Note that a low dielectric constant, as used herein, refers to any dielectric constant, K, of less than approximately 3.5; therefore, a low K dielectric, as used herein, refers to a dielectric having a dielectric constant of less than approximately 3.5.) Conductor filled trenches 34, 36, and 38 may be formed using any type of conductive material or combination of conductive materials, such as, for example, copper, copper alloys, aluminum, etc. Similarly, conductor filled trenches 34, 36, and 38 may also include a liner layer, as described above with reference to contacts 26, 28, and 30.

Semiconductor device 10 may also include a dielectric barrier layer 42. Dielectric barrier layer 42 is optional and may be used to prevent copper diffusion from underlying metal layer 41 into an overlying interlayer dielectric layer 44. As will be described below, dielectric barrier layer 42 may also serve as an etch stop layer. In one embodiment, dielectric barrier layer 42 may be formed of silicon nitride, silicon carbide, silicon carbon nitride, or any other appropriate material. Dielectric barrier layer 42 is typically blanket deposited over first metal layer 41. However, alternate embodiments may form dielectric barrier layer 42 selectively over conductor filled trenches 34, 36, and 38.

Semiconductor device 10, as illustrated in FIG. 1, also includes an interlayer dielectric 44 overlying dielectric barrier layer 42. (However, note that if dielectric layer 42 is not used, interlayer dielectric 44 would overlie first metal layer 41.) Optionally, an interfacial layer 43 may be present between dielectric barrier 42 and interlayer dielectric 44. For example, interfacial layer 43 may include an adhesion promoter layer (such as, for example, silanol-based compounds, amino-based compounds, and compounds with vinyl groups) or may be the result of extra processing steps at the onset of interlayer dielectric 44 formation. Furthermore, in some embodiments, interfacial layer 43 may include multiple layers (not shown). Interlayer dielectric 44 may be formed in a variety of ways, such as, for example, by a spin coat deposition process, a chemical vapor deposition (CVD) process, plasma enhanced CVD process (PECVD), etc. Interlayer dielectric 44 includes a low K dielectric material. For example, in one embodiment, interlayer dielectric 44 may be an organic low K dielectric material, such as, for example, silsesquioxane-based dielectrics or aromatic compounds. (As will be described in reference to subsequent FIGs., a conductor filled via will be formed within interlayer dielectric 44.) p Semiconductor device 10 of FIG. 1 also includes an optional interfacial layer 46 (similar to optional interfacial layer 43) overlying interlayer dielectric 44 and may include, for example, an adhesion promoter layer or may be the result of extra processing steps at the onset of intralayer dielectric 48. Furthermore, interfacial layer 46 can include multiple different layers (not shown).

Semiconductor device 10 also includes an intralayer dielectric 48 overlying optional interfacial layer 46. (That is, in an embodiment not having interfacial layer 46, intralayer dielectric 48 overlies interlayer dielectric layer 44.) In one embodiment, intralayer dielectric 48 may be formed in a variety of ways, such as, for example, by a spin coat deposition process, a chemical vapor deposition (CVD) process, plasma enhanced CVD (PECVD) process, etc. Intralayer dielectric 48 includes a low K dielectric material. However, intralayer dielectric 48 includes a different low K dielectric material as compared to interlayer dielectric 44. Generally, the materials for interlayer dielectric 44 and intralayer dielectric 48 are chosen such that etch chemistries used to form the trench openings in intralayer dielectric 48 will display an etch selectivity between intralayer dielectric 48 and interlayer dielectric 44, as will be described in more detail below. For example, in one embodiment, intralayer dielectric 48 may be a silicon based low K dielectric material, such as, for example, organosilicate glass (OSG), doped silica, porous silica, etc. In one embodiment, intralayer dielectric 48 includes silicon and oxygen. (As will be described in reference to subsequent FIGs., a conductor filled trench will be formed within intralayer dielectric 48.)

Semiconductor device 10 of FIG. 1 also includes an optional cap layer 50 formed overlying intralayer dielectric 48. Cap layer 50, if present, may protect underlying intralayer dielectric 48 from damage during subsequent chemical mechanical polishing (CMP). Cap layer 50 may also be used to prevent reaction between photoresist materials and intralayer dielectric 48, as well as to prevent damage to intralayer dielectric 48 during patterning rework processes. Cap layer 50 may be formed using any appropriate material, such as, for example silicon dioxide, silicon nitride, silicon carbide, etc. Alternatively, cap layer 50 may include multiple layers. Cap layer 50 may be formed by CVD, PECVD, spin coating, etc. Note that trench level dielectric stack 51 therefore includes optional interfacial layer 46, intralayer dielectric 48, and optional cap 50.

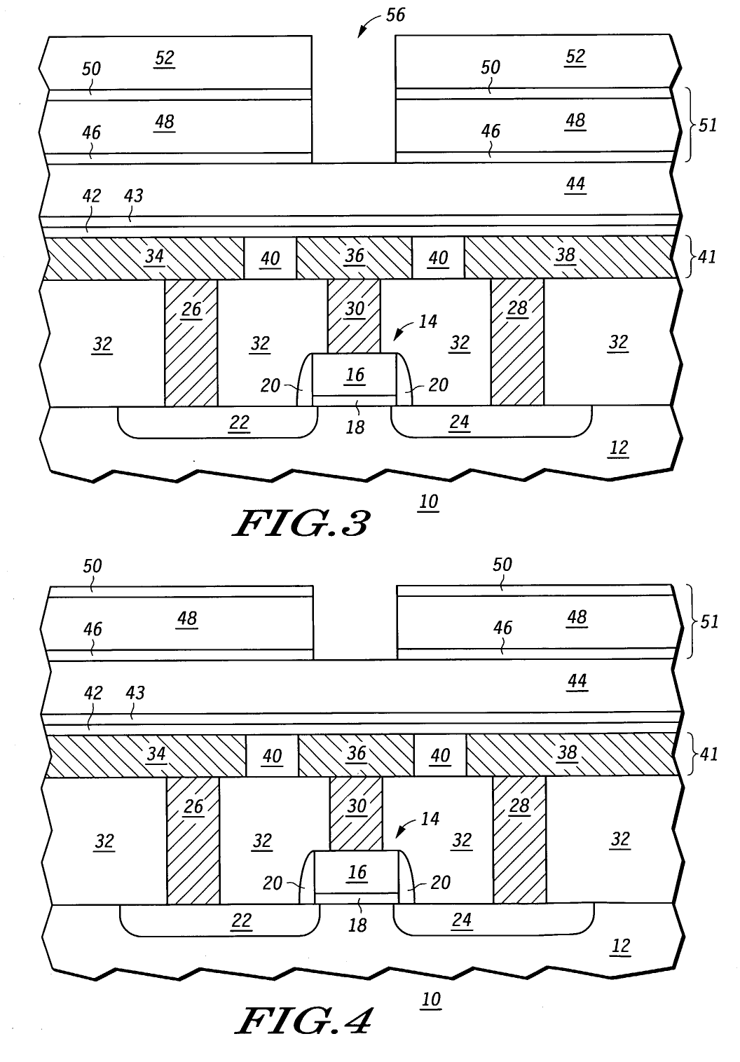

FIGS. 2-5 illustrate semiconductor device 10 during the formation of a via opening, in accordance with one embodiment of the present invention. FIG. 2 illustrates semiconductor device 10 after the formation of a masking layer 52, and a patterning of masking layer 52 to define via opening 54. In one embodiment, masking layer 52 may be a photoresist layer. Alternatively, a hardmask may be used. FIG. 3 illustrates semiconductor device 10 after etching through optional cap layer 50, intralayer dielectric 48 and optional interfacial layer 46 in order to transfer the via pattern from masking layer 52 to trench level dielectric stack 51 resulting in an opening 56. Opening 56 within trench level dielectric stack 51 may therefore be used to define the via opening in interlayer dielectric 44, as will be shown in subsequent FIGs. Also note that different etch chemistries may be used to etch through various portions of trench level dielectric stack 51. For example, in one embodiment, a fluorocarbon chemistry may be used to etch through the entire trench level dielectric stack 51 (assuming each layer of the trench level dielectric stack 51 is formed of silicon, oxygen, or a combination thereof); however, the particular fluorocarbon chemistry the may be tailored for each layer within trench level dielectric stack 51. In one embodiment, an aggressive etch chemistry may be used to etch through all of trench level dielectric stack 51 in a single processing step. Alternatively, each layer within trench level dielectric stack 51 (such as optional interfacial layer 46, intralayer dielectric 48, and optional cap layer 50) may be etched in a separate processing step. However, regardless of whether the etch is performed in one or more processing steps, the etch chemistry used for etching through each portion of trench level dielectric stack 51 is selective to interlayer dielectric 44 such that the etch stops on interlayer dielectric 44. Since the etch chemistry for trench level dielectric stack 51 is selective to the material of interlayer dielectric 44, interlayer dielectric 44 provides the etch stopping point for forming opening 56. This etch chemistry selectivity also allows for a more uniform and controllable trench depth across the die and wafer, as will be discussed more below in reference to FIG. 7.

FIG. 4 illustrates semiconductor device 10 after removal of masking layer 52. For example, if masking layer 52 is a photoresist layer, an ashing step may be used to remove it. Alternately, photoresist masking layer 52 may not be removed until after forming a via opening 58 as will be described later. FIG. 5 illustrates semiconductor device 10 after forming via opening 58 through interlayer dielectric 44 using trench level dielectric stack 51 as a hardmask. That is, the opening 56 is transferred to interlayer dielectric 44 without the need for additional sacrificial masking layers. The opening 58 may extend to the surface of the optional interfacial layer 43 or dielectric barrier 42, as shown in FIG. 5, or penetrate some portion of these layers. The benefit of not extending the opening 58 entirely through dielectric barrier 42 is that the underlying conductor filled trench 36 will remain capped during the subsequent trench etch. In one embodiment, an etch chemistry that is tailored for the organic dielectric used for interlayer dielectric 44 is used to form opening 58. For example, the etch chemistry for interlayer dielectric 44 may include, for example, an oxygen containing etch chemistry such as, O2/N2, O2/H2, O2/CxHy, O2/CO/NH3, etc.. Therefore, in one embodiment, a first etch chemistry can be used to etch interlayer dielectric 44 using dielectric barrier layer 42 as an etch stop. Afterwards, a different etch chemistry can be used to etch through dielectric barrier layer 42 (as will be discussed below in reference to FIG. 7). Also, using an etch chemistry for interlayer dielectric 44 that is selective to trench level dielectric stack 51 allows for the use of trench level dielectric stack 51 as a hardmask for etching through interlayer dielectric 44 (such as to form opening 58).

Note that in some embodiments interlayer dielectric 44 has a similar etch rate as compared to photoresist. In these embodiments, using a photoresist layer to define opening 58 within interlayer dielectric 44 would result in photoresist erosion. Thus, a thick photoresist layer would be required to fully etch through interlayer dielectric 44 and dielectric barrier layer 42 resulting in the compromise of pattern integrity. In order to ensure pattern integrity, a hardmask may be used instead of a photoresist mask. However, an additional hardmask adds process complexity and cost, and is also likely to add capacitance. Therefore, the use of trench level dielectric stack 51 as the hardmask for via patterning prevents the need for an additional hardmask while ensuring pattern integrity without increasing capacitance. However, note that in alternate embodiments, masking layer 52 may not be removed prior to forming via opening 58. In this embodiment, masking layer 52 may be removed during the formation of via opening 58, and any remaining portions may be removed after etching through interlayer dielectric 44 or after etching through dielectric barrier layer 42.

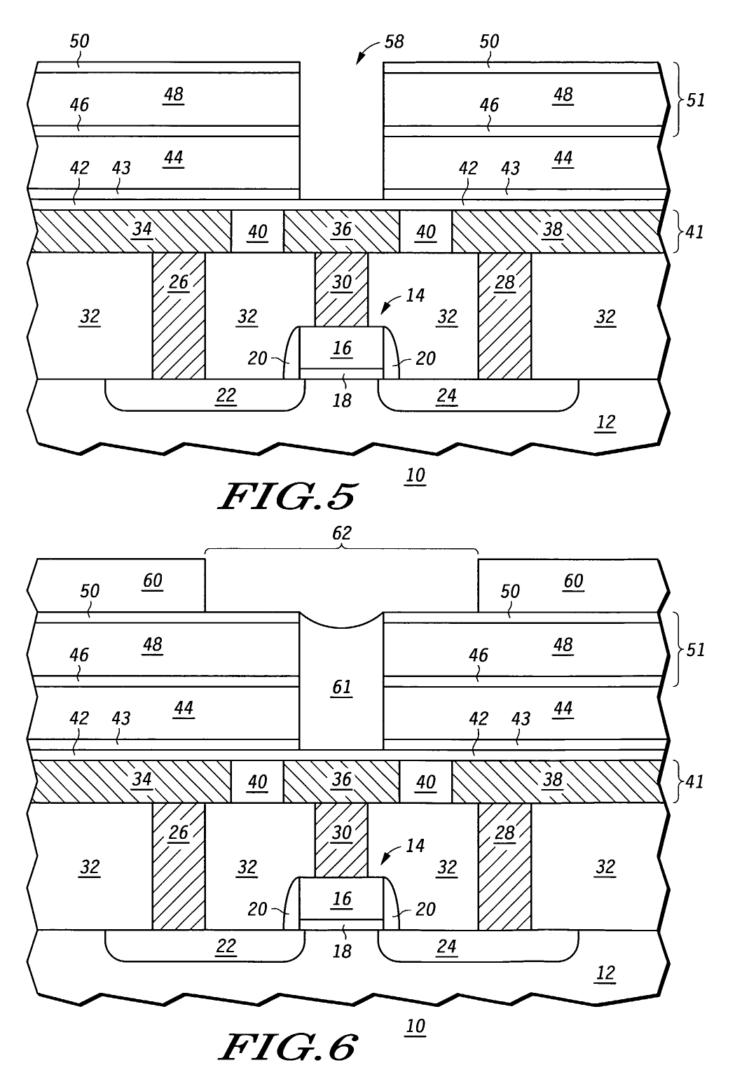

FIGS. 6-7 illustrate semiconductor device 10 during the formation of a trench opening, in accordance with one embodiment of the present invention. FIG. 6 illustrates semiconductor device 10 after the formation of a masking layer 60, and a patterning of masking layer 60 to define trench opening 62. In one embodiment, masking layer 60 may be a photoresist layer. Alternatively, a hardmask may be used. A via protection layer 61 is shown filling opening 58. The via protection layer 61 prevents the trench etch chemistry from damaging the underlying dielectrics layers 42, 43, 44, 51 and increasing the diameter of via opening 58. The via protection layer 61 may contain, for example, photoresist. In one embodiment, via protection layer 61 may be formed as a part of masking layer 60 such that masking layer 60 is formed over semiconductor device 10 and within opening 58, and then patterned to define trench opening 62, leaving behind the portion within opening 58 to form via protection layer 61. Alternatively, via protection layer 61 may be separate from masking layer 60. For example, in this embodiment, a photoresist layer may be coated on the wafer (such as with a spin on technique) and the portions of the photoresist layer overlying trench level dielectric stack 51 may be removed (such as by etching or polishing) such that a portion of the photoresist layer within opening 58 remains to form via protection layer 61. In this embodiment, maksing layer 60 is formed after formation of via protection layer 61. However, note that in alternate embodiments, no via protection layer 61 may be used.

FIG. 7 illustrates semiconductor device 10 after etching through optional cap layer 50, intralayer dielectric 48, and optional interfacial layer 46 in order to transfer the trench pattern from masking layer 60 to trench level dielectric stack 51 resulting in a via opening 65 within interlayer dielectric 44 and a trench opening 64 within intralayer dielectric 48. Additionally, any portions of optional interfacial layer 43 and dielectric barrier 42, not etched during formation of opening 58, are also etched within via opening 65. As described above in reference to creating opening 56 in FIG. 3, different etch chemistries may be used to etch through various portions of trench level dielectric stack 51. For example, in one embodiment, a fluorocarbon chemistry may be used to etch through the entire trench level dielectric stack 51; however, the particular fluorocarbon chemistry the may be tailored for each layer within trench level dielectric stack 51. As described in reference to creating opening 56 in FIG. 3, using an etch chemistry for trench level dielectric stack 51 that is selective to interlayer dielectric 44 allows for interlayer dielectric 44 to be used as the stopping point for etching trench opening 64. This allows for a more uniform and controllable trench depth across the die and wafer (as compared to the timed etches of the prior art described above) without the need of an additional etch stop layer between intralyer dielectric 48 and interlayer dielectric 44.

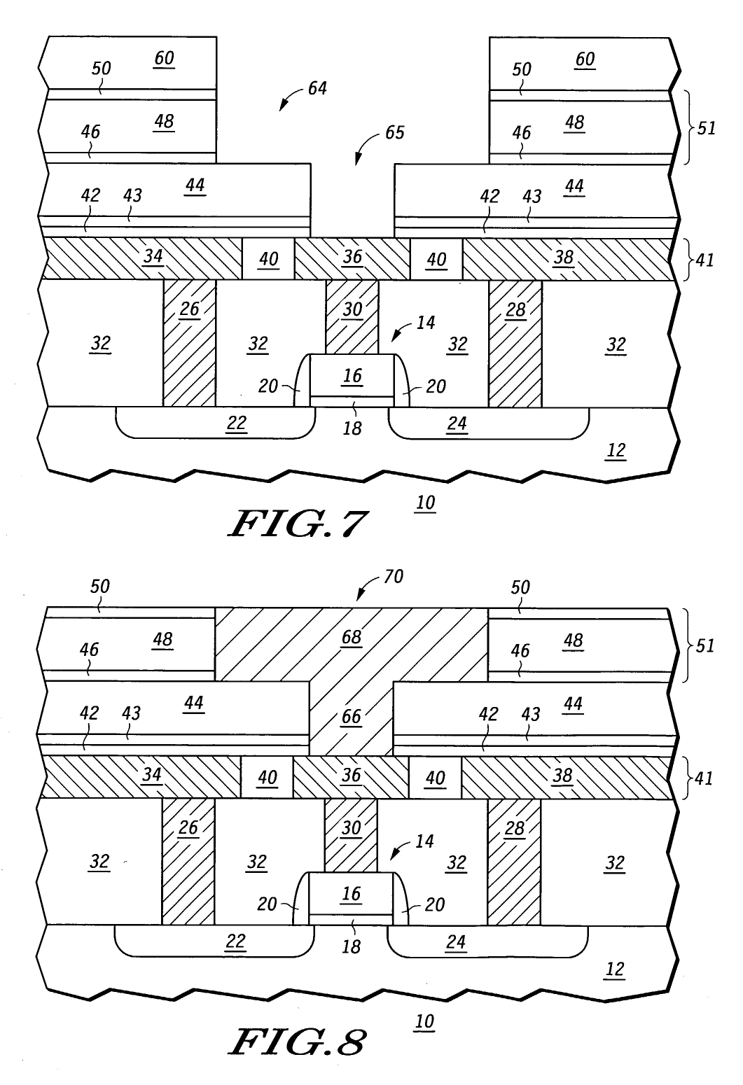

FIG. 8 illustrates semiconductor device 10 after the removal of masking layer 60 and the formation of conductor filled via 66 and conductor filled trench 68. After the formation of via opening 65 and trench opening 64 (shown in FIG. 7), a conductive layer (not shown) may be formed overlying intralayer dielectric 48 (and cap layer 50, if present) and within openings 64 and 65. Excess portions of the conductive layer overlying intralayer dielectric 48 (or cap layer 50, if present) may be removed, thus resulting in the interconnect structure 70 illustrated in FIG. 8 including conductor filled via 66 and conductor filled trench 68. The conductor can be any type of conductive material, such as, for example, copper, copper alloys, aluminum, etc. In one embodiment, the conductor can include multiple materials. For example, in one embodiment, conductor filled via 66 and conductor filled trench 68 may include a liner layer, where the liner layer may include, for example, titanium, titanium nitride, tantalum, tantalum nitride, titanium silicon nitride, tungsten nitride, tungsten carbon nitride, etc. The portions of the conductor overlying intralayer dielectric 48 (or cap layer 50, if present) may be removed using a polishing process, such as, for example, CMP.

Therefore, as illustrated in FIG. 8, note that the via filled portion 66 is embedded within a first low K layer (e.g. interlayer dielectric 44) and trench filled portion 68 is embedded within a second low K layer (e.g. intralayer dielectric 48), where the low K material used for the second low K layer (intralayer dielectric 48) is different from the low K material used for the first low K layer (interlayer dielectric 44). Therefore, the etch chemistry for etching through interlayer dielectric 44 is generally different from the etch chemistry used for etching through intralayer dielectric 48. Due to the difference in low K materials used for interlayer dielectric 44 and intralayer dielectric 48, an etch chemistry may be used to etch through interlayer dielectric 44 which is selective to intralayer 48. This selectivity allows for trench level dielectric stack 51 to be used as a hard mask for etching through interlayer dielectric 44, thus preventing the need for an additional mask. Also, due to the difference in low K materials, an etch chemistry may be used to etch through intralayer dielectric 48 which is selective to interlayer dielectric 44. As described above, this selectivity allows for the use of interlayer dielectric 44 as the etch stopping point which results in a more uniform trench depth across the die and wafer. The use of interlayer dielectric 44 as the etch stopping point also prevents the need for a separate additional etch stop layer between interlayer dielectric 44 and intralayer dielectric 48. Generally, this additional etch stop layer has a greater dielectric constant than the dielectric constants of the materials used for the interlayer and intralayer dielectrics, thus resulting in an increased capacitance. Therefore, note that in one embodiment, the selection of materials for interlayer dielectric 44 and intralayer dielectric 48 is based on the etch selectivity performance of their respective etch chemistries. Thus, the use of different low K materials and different etch chemistries for interlayer dielectric 44 and intralayer dielectric 48 results in a reduced capacitance and improved performance interconnect structure 70.

After formation of interconnect structure 70 of FIG. 8, subsequent interlayer and intralayer dielectrics may be formed overlying intralayer dielectric 48 (or cap layer 50, if present) to form more levels of interconnect structures. That is, semiconductor device 10 may include any number of interconnect levels where each interconnect level includes at least one interconnect structure (analogous to the resulting interconnect level illustrated in FIG. 8). After the multiple levels, further processing as known in the art may be performed to form a completed semiconductor device. Note that in one embodiment, only a portion of the multiple levels may include an interconnect structure like interconnect structure 70 of FIG. 8. That is, other levels may include interconnect structures which are different from interconnect structure 70 in terms of form or process. Alternatively, semiconductor device 10 may include only the single interconnect level as illustrated in FIG. 8. In this embodiment, further processing as known in the art may be performed after formation of the single interconnect level (having conductor filled trench 68 and conductor filled via 66) to form a completed device.

Although the embodiment illustrated in FIGS. 2-8 was described in reference to a via-first/trench-last dual inlaid method of forming interconnect structure 70, alternate embodiments may use a trench-first/via-last method to form the same resulting interconnect structure 70. For example, in FIG. 2, masking layer 52 is patterned to form an opening which defines the trench portion of interconnect structure 70. This opening in mask layer 52 is analogous to the opening 62 shown in FIG. 6. The pattern is then transferred to trench level dielectric stack 51 to form a trench opening. Masking layer 52 is then removed, and another masking layer may then be used to define a via opening corresponding to the via portion of interconnect structure 70. The pattern is then transferred to interlayer dielectric 44 to form a via opening, thus resulting in the structure of FIG. 7 (without masking layer 60) having via opening 65 and trench opening 64, where, in this embodiment, trench opening 64 is formed prior to via opening 65. Processing then continues as described above with reference to FIG. 8. Note that in this embodiment using the trench-first/via-last method, trench level dielectric stack 51 may no longer be used as a hardmask for creating via opening 65 because at the time of forming via opening 65, trench level dielectric stack 51 already includes trench opening 64, which is wider than via opening 65. Note also that in this embodiment, the same materials, processes, etch chemistries, etc. as described above in reference to FIGS. 1-8 may be used.

Also, although the embodiment illustrated in FIGS. 2-8 was described in reference to forming a dual inlaid interconnect structure (where openings 64 and 65 are both formed prior to being filled with a conductor), interconnect structure 70 may also be formed according to a single inlaid method. In this embodiment, after formation of dielectric barrier layer 42 (if necessary), optional interfacial layer 43, interlayer dielectric 44, and an optional cap layer (not shown) overlying interlayer dielectric 44 (similar to optional cap layer 50 described above), a masking layer is formed and patterned to define a via opening in interlayer dielectric 44. The pattern is then transferred to the optional cap layer, interlayer dielectric 44, optional dielectric barrier layer 42, and optional interfacial layer 43. The masking layer is then removed. Alternatively, the masking layer may be removed after etching through interlayer dielectric 44 rather than after optional dielectric barrier layer 42 and option interfacial layer 43, in which case, a subsequent etch is required to etch through dielectric barrier layer 42, if present. At this point, a conductive layer is formed over interlayer dielectric 44 and within the via opening. Portions of the conductive layer overlying the optional cap layer and interlayer dielectric 44 are then removed (such as, for example, by a CMP process), thus resulting in a conductor filled via (analogous to conductor filled via 66).

After formation of the conductor filled via, trench level dielectric stack 51 (including optional interfacial layer 46, intralayer dielectric 48, and optional cap layer 50) is formed overlying interlayer dielectric 44 and the conductor filled via. Also note that in this embodiment, trench level dielectric stack 51 may also include an additional dielectric barrier level (not shown) as the bottom layer of the stack (underlying optional interfacial layer 46, or, if not present, underlying intralayer dielectric 48). A masking layer is then formed over trench level dielectric stack 51 and patterned to define a trench opening. The pattern is then transferred to trench level dielectric stack 51. The masking layer is then removed. At this point, a conductive layer is formed over trench level dielectric stack 51 and within the trench opening. Portions of the conductive layer overlying trench level dielectric stack 51 are then removed (such as, for example, by a CMP process), to form a conductor filled trench analogous to conductor filled trench 68. Thus, this single inlaid method also results in the interconnect structure 70 that was previously described in reference to FIG. 8. Note also that the same materials, processes, etch chemistries, etc. described in FIGS. 1-8 may also be used for the single inlaid process and have therefore not been repeated in this portion of the description.

Therefore, it can be appreciated how interconnect structure 70 provides for improved control of trench depth without an increase in capacitance through the use of different low K dielectric materials for interlayer dielectric 44 and intralayer dielectric 48, as described above. Furthermore, various different methods may be used to form interconnect structure 70 and is not limited to those methods described herein.

In the foregoing specification, the invention has been described with reference to specific embodiments. However, one of ordinary skill in the art appreciates that various modifications and changes can be made without departing from the scope of the present invention as set forth in the claims below. For example, different materials than those mentioned and different processes than those mentioned may be used. Accordingly, the specification and figures are to be regarded in an illustrative rather than a restrictive sense, and all such modifications are intended to be included within the scope of present invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

What is claimed is:

1. A semiconductor device having an interconnect structure comprising:
a semiconductor substrate;
a first low dielectric constant layer formed over the semiconductor substrate;
a conductor-filled via embedded within the first low dielectric constant layer;
a second low dielectric constant layer over the first low dielectric constant layer, wherein the second low dielectric constant layer is different than the first low dielectric constant layer; and
a conductor-filled trench embedded within the second dielectric constant layer.

2. The semiconductor device of claim 1, wherein:
the second low dielectric constant layer comprises silicon and oxygen; and
the first low dielectric constant layer is an organic low dielectric constant layer.

3. The semiconductor device of claim 2, wherein the second low dielectric constant is an organosilicate glass (OSG).

4. The interconnect structure of claim 1, further comprising an interfacial layer between the first low dielectric constant layer and the second low dielectric constant layer.

5. The semiconductor device of claim 1, further comprising:
a patterned metal layer under and coupled to the conductor-filled via; and
a dielectric barrier layer between portions of the patterned metal layer and the first low dielectric constant layer.

6. The semiconductor device of claim 5, further comprising an interfacial layer between the first low dielectric constant material and the dielectric barrier layer.

7. The interconnect structure of claim 1, further comprising a cap layer over the second low dielectric constant layer.

8. The semiconductor device of claim 1, wherein the first low dielectric constant layer and the second low dielectric constant layer are formed by a method selected from the group of spin-on coating, chemical vapor deposition or plasma enhanced chemical vapor deposition.

9. A method of forming a semiconductor device comprising:
providing a semiconductor substrate;
forming a first low dielectric constant layer over the semiconductor substrate;
forming a second low dielectric constant layer over the first low dielectric constant layer;
forming a first patterned photoresist layer over the second low dielectric constant layer;
etching the second low dielectric constant layer with a first chemistry selective to the first low dielectric constant layer using the first patterned photoresist layer as a first mask to form a first opening;
etching the first low dielectric constant layer with a second chemistry to form a second opening, wherein the first low dielectric constant layer is different than the second low dielectric constant layer, and the second chemistry is different than the first chemistry; and
filling the first opening and the second opening with a conductive material.

10. The method of claim 9, wherein the first chemistry comprises a fluorocarbon and the second chemistry comprises oxygen.

11. The method of claim 9, wherein the second opening is under the first opening.

12. The method of claim 11, wherein etching the second low dielectric constant layer further comprises exposing the first low dielectric constant layer within the first opening.

13. The method of claim 12, wherein etching the first low dielectric constant layer further comprises using the second low dielectric constant layer as a hardmask after etching the second low dielectric constant layer.

14. The method of claim 13, further comprising removing the first patterned photoresist layer.

15. The method of claim 14, further comprising forming a second patterned photoresist layer used as a second mask for etching the second low dielectric constant layer.

16. The method of claim 9, further comprising:
forming a transistor over the semiconductor substrate;
forming a patterned conductive layer over the transistor; and
forming a contact over the transistor to couple a terminal of the transistor to the patterned conductive layer; and wherein:
the first low dielectric constant layer is formed over the patterned conductive layer.

17. The method of claim 16, further comprising forming a barrier layer between the patterned conductive layer and the first low dielectric constant layer.

18. The method of claim 17, further comprising forming an interfacial layer between the barrier layer and the first low dielectric constant layer.

19. The method of claim 9, further comprising forming an interfacial layer between the first low dielectric constant layer and the second low dielectric constant layer.

20. The method of claim 9, further comprising forming a cap layer over the second low dielectric constant layer.

21. The method of claim 9, wherein forming the first low dielectric constant layer is performed by a method selected from the group consisting of spin-coating, chemical vapor deposition and plasma enhanced chemical vapor deposition.

22. The method of claim 9, wherein forming the second low dielectric constant layer is performed by a method selected from the group consisting of spin-coating, chemical vapor deposition and plasma enhanced chemical vapor deposition.

23. A method of forming a semiconductor device comprising:
providing a semiconductor substrate;
forming a first low dielectric constant layer over the semiconductor substrate;
forming a second low dielectric constant layer over the first low dielectric constant layer;
forming a first patterned photoresist layer over the second low dielectric constant layer;
etching the second low dielectric constant layer with a first chemistry selective to the first low dielectric constant layer using the first patterned photoresist layer as a first mask to form a first opening and exposing the first low dielectric constant material;
removing the first patterned photoresist layer;
etching the first low dielectric constant layer with a second chemistry using at least the second low dielectric constant layer as a second mask to form a second opening, wherein the first low dielectric constant layer is different than the second low dielectric constant layer, and the second chemistry is different than the first chemistry;
forming a second patterned photoresist layer over the second low dielectric constant layer;
etching the second low dielectric constant layer using the second patterned photoresist layer as a mask to form a third opening; and
filling the second opening and the third opening with a conductive material.
